(19) United States
(12) Patent Application Publication
(10) Pub. No.: US 2016/0327861 A1
(43) Pub. Date: Nov. 10, 2016

(54) PHOTOSENSITIVE DRY FILM COMPOSITIONS

(71) Applicant: E I DU PONT DE NEMOURS AND COMPANY, Wilmington, DE (US)

(72) Inventors: Thomas K. Foreman, Sayre, PA (US); YUNG-CHUNG CHEN, MIAOLI COUNTY (TW)

(21) Appl. No.: 15/147,424

(22) Filed: May 5, 2016

Related U.S. Application Data
(60) Provisional application No. 62/156,947, filed on May 5, 2015.

(51) Int. Cl. G03F 7/016

(52) U.S. Cl. CPC G03F 7/0163

(57) ABSTRACT

A photosensitive dry film composition includes a hexaarylbiimidazole blend, a photosensitizer that absorbs in the 350 to 410 nm wavelength range and a hydrogen donor. The hexaarylbiimidazole blend includes a hexaarylbiimidazole having a molar extinction coefficient of at least 4,000 in the 350 to 410 nm wavelength range and a hexaarylbiimidazole having a molar extinction coefficient of less than 4,000 in the 350 to 410 nm wavelength range.

### BACKGROUND INFORMATION

1. Field of the Disclosure

This disclosure relates to photosensitive dry film compositions.

2. Description of the Related Art

Conventional photoinitiator systems for photodefinable dry film applications typically use a substituted hexaarylbiimidazole (HABI) to either directly or indirectly absorb the light energy and begin the photoinduced reactions that eventually result in free radical polymerization within the photoresist. In such conventional applications, the photoinitiator is typically optimized to be photosensitive at a particular wavelength, most commonly about 355 nm or about 405 nm, or in some cases about 375 nm, depending on the light output of the imaging system being used. Photoinitiation exposure can be done via a photomask, laser direct imaging (LDI), light emitting diode (LED) exposure or other conventional means for patterning a dry film. LDI is often preferred due to a number of processing advantages over other methods.

Creating a photoinitiator system useful for the direct imaging segment that functions satisfactorily at both 355 nm and 405 nm involves significant technical obstacles. As light wavelengths increase, HABIs tend to exhibit decreased absorption of light, so a HABI's absorption at 405 nm will be less than at 355 nm. To increase absorption at 405 nm, the HABI concentration in the film can be increased, but then the absorption of light will tend to be too high at the shorter wavelength (355 nm). When the light absorption of the photoresist is too high at a particular wavelength, upon exposure, not enough light will penetrate to the base of the resist, resulting in less photopolymerization at the resist/substrate interface, which will result in lower quality photoresist lines during the development process. When the light absorption of the photoresist is too low, the photoreactivity (photospeed) of the photoresist will be slow, which will then result in commercially impractical processing times.

U.S. Patent Application No. 2012/0270142 A1 to Lee, et al. discloses a photosensitive composition and a method of manufacturing a substrate used for a display device. The photosensitive composition includes an acrylic based copolymer, a photoinitiator, a photosensitizer and a solvent. Lee et al. describes a method to improve photosensitivity at certain wavelengths. A need exists, however, for photosensitive compositions that are photosensitive at multiple wavelengths, particularly for dry film applications.

### SUMMARY

A photosensitive dry film composition includes a hexaarylbiimidazole blend, a photosensitizer that absorbs in the 350 to 410 nm wavelength range and a hydrogen donor. The hexaarylbiimidazole blend includes a hexaarylbiimidazole having a molar extinction coefficient of at least 4,000 in the 350 to 410 nm wavelength range and a hexaarylbiimidazole having a molar extinction coefficient of less than 4,000 in the 350 to 410 nm wavelength range.

The foregoing general description and the following detailed description are exemplary and explanatory only and are not restrictive of the invention, as defined in the appended claims.

### DETAILED DESCRIPTION

A photosensitive dry film composition includes a hexaarylbiimidazole blend, a photosensitizer that absorbs in the 350 to 410 nm wavelength range and a hydrogen donor. The hexaarylbiimidazole blend includes a hexaarylbiimidazole having a molar extinction coefficient of at least 4,000 in the 350 to 410 nm wavelength range and a hexaarylbiimidazole having a molar extinction coefficient of less than 4,000 in the 350 to 410 nm wavelength range.

In one embodiment, the hexaarylbiimidazole having a molar extinction coefficient of at least 4,000 in the 350 to 410 nm wavelength range includes an ortho electron withdrawing substitution on a 2-phenyl ring and an electron donating substitution on a 4-phenyl ring, a 5-phenyl ring, or both the 4-phenyl and the 5-phenyl rings. In a specific embodiment, the hexaarylbiimidazole having a molar extinction coefficient of at least 4,000 in the 350 to 410 nm wavelength range is selected from the group consisting of: biimidazole, 2,2′,4,4′-tetrakis(2-chlorophenyl)-5,5′-bis(3,4-dimethoxyphenyl)-, 1,1′-bi-1H-imidazole, 2,2′,4-tris(2-chlorophenyl)-5-(3,4-dimethoxyphenyl)-4′,5′-diphenyl- and mixtures thereof.

In another embodiment, the hexaarylbiimidazole having a molar extinction coefficient of at least 4,000 in the 350 to 410 nm wavelength range is present in a range of from about 0.5 to about 2.5 wt % based on the total weight of the dry film.

In yet another embodiment, the hexaarylbiimidazole having a molar extinction coefficient of less than 4,000 in the 350 to 410 nm wavelength range includes an ortho electron withdrawing substitution on a 2-phenyl ring. In a specific embodiment, the hexaarylbiimidazole having a molar extinction coefficient of less than 4,000 in the 350 to 410 nm wavelength range is 2,2′-bis(2-chlorophenyl)-4,4′,5,5′-tetraphenyl-1,2′-biimidazole.

In still yet another embodiment, the hexaarylbiimidazole having a molar extinction coefficient of less than 4,000 in the 350 to 410 nm wavelength range is present in a range of from about 1.0 to about 3.5 wt % based on the total weight of the dry film.

In a further embodiment, the photosensitizer is selected from the group consisting of 2-propanone, 1,3-bis(1,3-dihydro-1,3,3-trimethyl-2H-indol-2-ylidene)-, 1H,5H,11H-[1]benzopyrano[6,7,8-ij]quinolizin-11-one, 2,3,6,7-tetrahydro-9-methyl-, 9,10-dibutoxyanthracene and mixtures thereof.

In still a further embodiment, the photosensitizer is present in a range of from about 0.1 to about 0.3 wt % based on the total weight of the dry film.

In yet a further embodiment, the hydrogen donor is selected from the group consisting of N-phenyl glycine, tribromomethyl phenyl sulfone and mixtures thereof.

In still yet a further embodiment, the photosensitive dry film composition further includes a binder. In a specific embodiment, the binder includes a methacrylic acid, a methyl methacrylate, a butyl methacrylate, a benzyl methacrylate, a styrene or a mixture thereof. In another specific embodiment, the binder has a weight average molecular weight in a range of from about 20,000 to about 100,000.

Many aspects and embodiments have been described above and are merely exemplary and not limiting. After reading this specification, skilled artisans appreciate that other aspects and embodiments are possible without departing from the scope of the invention. Other features and advantages of the invention will be apparent from the following detailed description, and from the claims.

### Definitions

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”. Unless stated otherwise, all percentages, parts, ratios, etc., are by weight.

When the term “about” is used in describing a value or an end-point of a range, the disclosure should be understood to include the specific value or end-point referred to.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

Photosensitive dry film compositions of the present disclosure are photosensitive to at least two distinct wavelengths of radiation, thereby accommodating more than one type of electromagnetic radiation source (e.g., laser light) for photoimaging the photosensitive dry film composition. Unlike conventional direct imaging photoinitiator systems, e.g. direct imaging applications that are optimized to one particular wavelength (generally either 355 nm, 375 nm or 405 nm), the photoinitiator systems of the present disclosure are optimized to use at least two wavelengths (typically selected from 355 nm, 375 nm and 405 nm), so that the photoimageable dry film is useful with multiple types of photoimaging equipment. The photosensitive dry film compositions of the present disclosure include a blend of at least two types of HABI compounds as hydrogen acceptors and function satisfactorily at both wavelengths.

In one embodiment, a HABI blend is used in combination with an appropriate HABI photosensitizer to achieve the desired absorption and photoreactivity at both 355 nm and 405 nm in a single photoresist. In this embodiment, a photosensitive dry film includes:
(A) a blend of hexaarylbiimidazoles (HABIs) wherein:
   (i) at least one HABI is selected from a group having a molar extinction coefficient of at least 4,000 in the 350 to 410 nm wavelength range (h-HABI), and
   (ii) at least one HABI selected from a group having a molar extinction coefficient of less than 4,000 in the 350 to 410 nm wavelength range (I-HABI);
(B) a photosensitizer that absorbs in the 350 to 410 nm wavelength range; and
(C) a hydrogen donor.

Molar extinction coefficients are directly related to the absorption strength of the HABI within the wavelength range and directly contribute to the strength of the dry film absorption within the wavelength range. If the dry film absorption within the wavelength range is too high, then not enough light can penetrate the dry film to give uniform photoreactivity. This results in a dry film with unacceptable functionality. The acceptable dry film absorption within the wavelength range is generally accepted to be 0.4 to 0.8. The HABI extinction coefficient ranges described in (A) above allow the dry film to have good absorption throughout the wavelength range, enabling the desired photosensitivity at multiple wavelength throughout the range.

Examples of h-HABIs are HABIs having an ortho electron withdrawing substitution (e.g. chloro) on the 2-phenyl ring and an electron donating substitution (e.g. methoxy) on either one or both of the 4-phenyl and 5-phenyl rings. h-HABIs may also have electron withdrawing substitution on the 4-phenyl and/or 5-phenyl rings. Specific examples of h-HABIs include:
a. TCTM-HABI (CAS# 233767-21-0; biimidazole, 2,2′,4,4′-tetrakis(2-chlorophenyl)-5,5′-bis(3,4-dimethoxyphenyl)-);
b. TCDM-HABI (CAS# 100486-97-3; 1,1′-bi-1H-imidazole, 2,2′,4-tris(2-chlorophenyl)-5-(3,4-dimethoxyphenyl)-4′,5′-diphenyl-); and
c. Derivations of TCTM-HABI and TCDM-HABI, where the derivation does not cause the molar extinction coefficient of the h-HABI to fall below 4000 in the 350 to 410 nm wavelength range.

In one embodiment, the amount of h-HABI in the photosensitive dry film composition is in a range of from about 0.5 to about 2.5 wt % based on the total weight of the dry film. In a more specific embodiment, the amount of h-HABI in the photosensitive dry film composition is in a range of from about 1.0 to about 2.0 wt % based on the total weight of the dry film. Examples of 1-HABIs are HABIs having an ortho electron withdrawing substitution (e.g. chloro) on the 2-phenyl ring and may also have electron withdrawing substitution on the 4-phenyl and/or 5-phenyl rings. Specific examples of 1-HABIs include:
a. CI-HABI (CAS# 7189-82-4; 2,2′-bis(2-chlorophenyl)-4,4′,5,5′-tetraphenyl-1,2′-biimidazole); and
b. Derivations of CI-HABI, where the derivation does not cause the molar extinction coefficient of the 1-HABI to rise above 4000 in the 350 to 410 nm wavelength range.

In one embodiment, the amount of 1-HABI in the photosensitive dry film composition is in a range of from about 1.0 to about 3.5 wt % based on the total weight of the dry film. In a more specific embodiment, the amount of I-HABI in the photosensitive dry film composition is in a range of from about 1.5 to about 2.5 wt % based on the total weight of the dry film.

Examples of photosensitizers include:
a. Bis-Fischer's Base Ketone (BFBK; CAS# 24293-93-4; 2-propanone, 1,3-bis(1,3-dihydro-1,3,3-trimethyl-2H-indol-2-ylidene)-);
b. Coumarin 480 (CAS# 41267-76-9; 1H,5H,11H-[1]benzopyrano[6,7,8-ij]quinolizin-11-one, 2,3,6,7-tetrahydro-9-methyl-); and
c. 9,10-dibutoxyanthracene (CAS# 76275-14-4); and d. Derivatives of any of the above photosensitizers, where the derivation does not harm the dual wavelength performance of the photosensitive dry film composition.

In one embodiment, the amount of photosensitizer in the photosensitive dry film composition is in a range of from about 0.05 to about 1.0 wt % based on the total weight of the dry film. In a more specific embodiment, the amount of photosensitizer in the photosensitive dry film composition is in a range of from about 0.1 to about 0.3 wt % based on the total weight of the dry film.

Examples of hydrogen donors include:
a. NPG (CAS#103-01-5; N-phenyl glycine); and
b. TBMPS (CAS# 17025-47-7; tribromomethyl phenyl sulfone); and
c. Derivatives of NPG and TBMPS, where the derivation does not affect the radical transfer efficiency.

In one embodiment, solvent can be incorporated into the precursor of the photosensitive compositions of the present disclosure to lower viscosity to thereby allow application of the material in precise layers. Once the layer is created, the solvent can be volatilized away to leave the photosensitive dry film composition of the present disclosure. Examples of solvents include alcohols (e.g., methanol, ethanol, propanol, butanol and the like), ethers (e.g., tetrahydrofuran) and ketones (e.g., acetone, methyl ethyl ketone).

In one embodiment, a binder polymer having a weight average molecular weight (M_{w}) in a range of from about 20,000 to about 100,000 may be included in the photosensitive dry film composition. In one embodiment, the binder may have a basic composition including a methacrylic acid (MAA), a methyl methacrylate (MMA), a butyl methacrylate (BMA), a benzyl methacrylate (BzMA), an ethyl acrylate (EA), a styrene, or a mixture thereof. The binder can improve film forming properties of the photosensitive dry film, as well as enabling processing in aqueous-based developer and stripper solutions.

In one embodiment, a monomer may be included in the photosensitive dry film composition that enables crosslinking of specific regions of the dry film during the photoreaction that makes these specific regions insoluble in the developer solution. The polymerizable group of the monomer can have either an acrylic functionality, methacrylic functionality, or a combination of the two. The backbone of the monomer can contain aliphatic, aromatic, urethane, ethoxylate, or propoxylate moieties to interconnect the polymerizable groups.

In one embodiment, a surfactant can be used to improve coating properties of a dry film precursor material. Examples of surfactants include polyoxyethylene octylphenyl ether, polyoxy ethylene nonyl phenylether, F171, F172, and F173 (available from Dainippon Ink & Chemicals, Japan), FC430 and FC431 (Sumitomo 3M Ltd., Japan), KP341 (Shinetsu Chemical Co., Japan), among others. These may be used alone or as a mixture thereof.

In one embodiment, the photosensitive dry film compositions of the present disclosure may further include additives such as thermo polymerization inhibitors, defoaming agents, etc. In some embodiments, the photosensitive dry film composition may further include pigments and/or dyes.

The photosensitive dry film compositions of the present disclosure are photosensitive to at least two distinct wavelengths of radiation, thereby accommodating more than one type of electromagnetic radiation source. In one embodiment, with a 355 nm exposure process, the maximum acceptable exposure energy cutoff to obtain 18 steps held with a 41-step density step wedge can be in a range of from about 10 to about 25 mJ/cm². In a more specific embodiment, the maximum acceptable exposure energy cutoff can be in a range of from about 10 to about 15 mJ/cm². In a still more specific embodiment, the maximum acceptable exposure energy cutoff can be about 12 mJ/cm². In one embodiment, with a 405 nm exposure process the maximum acceptable exposure energy cutoff to obtain 18 steps held with a 41-step density step wedge can be in a range of from about 40 to about 120 mJ/cm². In a more specific embodiment, the maximum acceptable exposure energy cutoff to obtain 18 steps held can be in a range of from about 60 to about 100 mJ/cm². In a still more specific embodiment, the maximum acceptable exposure energy cutoff to obtain 18 steps held can be about 90 mJ/cm². In one embodiment, the photosensitive dry film compositions of the present disclosure are capable of meeting the exposure energy cutoff criteria for both a 355 nm exposure and a 405 nm exposure.

### EXAMPLES

The concepts described herein will be further described in the following examples, which do not limit the scope of the invention described in the claims.

Photoresist dry film compositions for Example 1 (E1) and Comparative Examples 1 and 2 (CE1 and CE2) were prepared from liquid compositions by dissolving the ingredients listed in Table 1 in solvent (a 90/10 w/w acetone/methanol blend). All values listed in Table 1 are in weight percent of the dry film. 30 wt % solids solutions were cast onto 19 μm thick polyethylene terephthalate (PET) substrates. The coatings were dried at room temperature. The dried photoresist film thickness was 30 μm.

TABLE 1

| Ingredient | E1 | CE1 | CE2 |
|---|---|---|---|
| Binder 1 | 54.19 | 54.19 | 54.19 |
| Binder 2 | 2.85 | 2.85 | 2.85 |
| Ethoxylated (17) bis-phenol A dimethacrylate | 22.08 | 24.58 | 23.38 |
| Trimethyolpropane trimethacrylate | 5.82 | 5.82 | 5.82 |
| Monomer 3 | 4.67 | 4.67 | 4.67 |
| Ethoxylated (14) ethyleneglycol dimethacrylate | 3.18 | 3.18 | 3.18 |
| Victoria green dye | 0.04 | 0.04 | 0.04 |
| Leuco crystal violet | 0.70 | 0.70 | 0.70 |
| Pluronic ® 31R1 | 2.49 | 2.49 | 2.49 |
| Triazole | 0.04 | 0.04 | 0.04 |
| N-phenyl glycine | 0.05 | 0.05 | 0.05 |
| TCDM-HABI | 1.30 | 1.30 | — |
| CI-HABI | 2.50 | — | 2.50 |
| Bis-Fischer's Base Ketone | 0.10 | 0.10 | 0.10 |

Binder 1 = 32 MMA/18 BMA/25 MAA/25 styrene; 55,000 Mw
Binder 2 = 35 MMA/20 BMA/25 EA/20 MAA; 80,000 Mw
Monomer 3 = 85/15 Aliphatic urethane triacrylate in HDDA; Urethane oligomer 2,000 Mw

Photoresist films E1, CE1 and CE2 were laminated to a brush scrubbed copper substrates using a HRL-24 laminator (E.I du Pont de Nemours and Co., Wilmington, Del.). The laminations were done at a temperature of 100° C./100° C. and a speed of 1 m/min with 3 kg/cm² roll pressure. After lamination, the samples were allowed to cool to room temperature. A 41-step density step wedge (Stouffer Industries, Inc., Mishawaka, Ind.) was then place on top of the PET and the exposure step was conducted. This was done with either an Paragon ^{TM} 8800 laser direct imager (Orbotech Inc., Billerica, Mass.) for exposure at 355 nm, or a UVE-M552 UV exposure system (C-Sun Manufacturing, Ltd., Taiwan) fitted with a 405 nm narrow bandpass filter for exposure at 405 nm. After exposure each sample was developed using a conveyorized developer. The development chemistry was 1 wt % sodium carbonate in water at 30° C. After rinsing with water and drying, the last step held on the step wedge was recorded. A range of exposure energies was used for each photoresist. Table 2 shows the energy required to obtain 18 steps held (Stouffer 41 Step Wedge) for each of the photoresists.

As is shown in Table 2, only Example 1 (E1) met the acceptable energy criteria for both 355 nm and 405 nm exposure processes (i.e., 12 mJ/cm² at 355 nm and 90 mJ/cm² at 405 nm), while both CE1 and CE2 were acceptable at one wavelength, but not the other.

TABLE 2

Energy Required for 18 Steps (mJ/cm²)

| Example | 355 nm Irradiation¹ | 405 nm Irradiation² |
|---|---|---|
| E1 | 9 | 70 |
| CE1 | 8 | 140 |
| CE2 | 19 | 80 |

¹Conducted with Orbotech Paragon ™ 8800 laser light source machine.
²Conducted with C-Sun UVE-M552 conventional mercury lamp light source machine fitted with a 405 nm narrow bandpass filter.

The procedure for E1 was used for Examples 2-5 (E2-E5) shown in Table 3, but the focus was on varying the TCDM and CI-HABI concentrations in combination with the photosensitizer, Bis-Fischer's Base

Ketone. The exposure energy required for each to achieve 18 steps held is shown in Table 4. In these examples, it is shown that with at least 1.50 wt % of CI-HABI, a balance in the exposure energy at 355 nm and 405 nm can be achieved. In addition, the results in Table 5 demonstrate that an acceptable number of steps held can be achieved by using a Nuvogo™ 800 system (Orbotech) with 375 nm and/or 405 nm radiation.

TABLE 3

| Ingredient | E2 | E3 | E4 | E5 |
|---|---|---|---|---|
| Binder 1 | 54.19 | 54.19 | 54.19 | 54.19 |
| Binder 2 | 2.85 | 2.85 | 2.85 | 2.85 |
| Ethoxylated (17) bis-phenol A | 22.08 | 22.58 | 22.24 | 23.38 |
| dimethacrylate | | | | |
| Trimethyolpropane trimethacrylate | 5.82 | 5.82 | 5.82 | 5.82 |
| Monomer 3 | 4.67 | 4.67 | 4.67 | 4.67 |
| Ethoxylated (14) ethyleneglycol | 3.18 | 3.18 | 3.18 | 3.18 |
| dimethacrylate | | | | |
| Victoria green dye | 0.04 | 0.04 | 0.04 | 0.04 |
| Leuco crystal violet | 0.70 | 0.70 | 0.70 | 0.70 |
| Pluronic ® 31R1 | 2.49 | 2.49 | 2.49 | 2.49 |
| Triazole | 0.04 | 0.04 | 0.04 | 0.04 |
| N-phenyl glycine | 0.05 | 0.05 | 0.05 | 0.05 |
| TCDM-HABI | 1.30 | 1.30 | 1.04 | 1.30 |
| CI-HABI | 2.50 | 2.00 | 2.50 | 1.50 |
| Bis-Fischer's Base Ketone | 0.10 | 0.10 | 0.10 | 0.10 |

Binder 1 = 32 MMA/18 BMA/25 MAA/25 styrene; 55,000 Mw
Binder 2 = 35 MMA/20 BMA/25 EA/20 MAA; 80,000 Mw
Monomer 3 = 85/15 Aliphatic urethane triacrylate in HDDA; Urethane oligomer 2,000 Mw

TABLE 4

Energy Required for 18 Steps (mJ/cm²)

| Example | 355 nm Irradiation¹ | 405 nm Irradiation² |
|---|---|---|
| E2 | 9 | 70 |
| E3 | 9 | 70 |
| E4 | 9 | 70 |
| E5 | 9 | 88 |

¹Conducted with Orbotech Paragon ™ 8800 laser light source machine.
²Conducted with C-Sun UVE-M552 conventional mercury lamp light source machine fitted with a 405 nm narrow bandpass filter.

TABLE 5
Number of Steps Held (41SS)

| 375 nm | 375/405 nm | 405 nm |
|---|---|---|
| 25 | 23 | 20 |

¹Conducted with Nuvogo ™ 800 system with 30 mJ exposure energy.

Note that not all of the activities described above in the general description or the examples are required, that a portion of a specific activity may not be required, and one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof has been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all of the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any sub-combination. Further, references to values stated in ranges include each and every value within that range.

What is claimed is:

1. A photosensitive dry film composition comprising:
a hexaarylbiimidazole blend, wherein the hexaarylbiimidazole blend comprises a hexaarylbiimidazole having a molar extinction coefficient of at least 4,000 in the 350 to 410 nm wavelength range and a hexaarylbiimidazole having a molar extinction coefficient of less than 4,000 in the 350 to 410 nm wavelength range;
a photosensitizer that absorbs in the 350 to 410 nm wavelength range; and
a hydrogen donor.

2. The photosensitive dry film composition of claim 1, wherein the hexaarylbiimidazole having a molar extinction coefficient of at least 4,000 in the 350 to 410 nm wavelength range comprises:
an ortho electron withdrawing substitution on a 2-phenyl ring; and
an electron donating substitution on a 4-phenyl ring, a 5-phenyl ring, or both the 4-phenyl and the 5-phenyl rings.

3. The photosensitive dry film composition of claim 2, wherein the hexaarylbiimidazole having a molar extinction coefficient of at least 4,000 in the 350 to 410 nm wavelength range is selected from the group consisting of:
biimidazole, 2,2′,4,4′-tetrakis(2-chlorophenyl)-5,5′-bis(3,4-dimethoxyphenyl)-,
1,1′-bi-1H-imidazole, 2,2′,4-tris(2-chlorophenyl)-5-(3,4-dimethoxyphenyl)-4′,5′-diphenyl- and
mixtures thereof.

4. The photosensitive dry film composition of claim 1, wherein the hexaarylbiimidazole having a molar extinction coefficient of at least 4,000 in the 350 to 410 nm wavelength range is present in a range of from about 0.5 to about 2.5 wt % based on the total weight of the dry film.

5. The photosensitive dry film composition of claim 1, wherein the hexaarylbiimidazole having a molar extinction coefficient of less than 4,000 in the 350 to 410 nm wavelength range comprises an ortho electron withdrawing substitution on a 2-phenyl ring.

6. The photosensitive dry film composition of claim 5, wherein the hexaarylbiimidazole having a molar extinction coefficient of less than 4,000 in the 350 to 410 nm wavelength range is 2,2′-bis(2-chlorophenyl)-4,4′,5,5′-tetraphenyl-1,2′-biimidazole.

7. The photosensitive dry film composition of claim 1, wherein the hexaarylbiimidazole having a molar extinction coefficient of less than 4,000 in the 350 to 410 nm wavelength range is present in a range of from about 1.0 to about 3.5 wt % based on the total weight of the dry film.

8. The photosensitive dry film composition of claim 1, wherein the photosensitizer is selected from the group consisting of:
2-propanone, 1,3-bis(1,3-dihydro-1,3,3-trimethyl-2H-indol-2-ylidene)-,
1H,5H,11H-[1]benzopyrano[6,7,8-ij]quinolizin-11-one, 2,3,6,7-tetrahydro-9-methyl-,
9,10-dibutoxyanthracene and mixtures thereof.

9. The photosensitive dry film composition of claim 1, wherein the photosensitizer is present in a range of from about 0.1 to about 0.3 wt % based on the total weight of the dry film.

10. The photosensitive dry film composition of claim 1, wherein the hydrogen donor is selected from the group consisting of N-phenyl glycine, tribromomethyl phenyl sulfone and mixtures thereof.

11. The photosensitive dry film composition of claim 1, further comprising a binder.

12. The photosensitive dry film composition of claim 11, wherein the binder comprises a methacrylic acid, a methyl methacrylate, a butyl methacrylate, a benzyl methacrylate, an ethyl acrylate, a styrene or a mixture thereof.

13. The photosensitive dry film composition of claim 11, wherein the binder has a weight average molecular weight in a range of from about 20,000 to about 100,000.
